(19) United States
(12) Patent Application Publication
(10) Pub. No.: US 2026/0206400 A1
(43) Pub. Date: Jul. 16, 2026

(54) LIGHT-EMITTING PACKAGE STRUCTURE AND LIGHT-EMITTING DEVICE

(71) Applicant: LITE-ON TECHNOLOGY CORPORATION, TAIPEI CITY (TW)

(72) Inventors: WEI-HSUN HSU, TAOYUAN CITY (TW); HONG-YE LAI, Taichung City (TW); Kai-Chieh Liang, New Taipei City (TW); SHENG-YUN WANG, New Taipei City (TW); TUNG-HSIANG CHUANG, TAIPEI CITY (TW)

(21) Appl. No.: 19/553,411

(22) Filed: Mar. 1, 2026

Related U.S. Application Data
(63) Continuation-in-part of application No. 17/706,376, filed on Mar. 28, 2022, now Pat. No. 12,604,579.
(60) Provisional application No. 63/168,266, filed on Mar. 31, 2021.
(60) Provisional application No. 63/180,055, filed on Apr. 26, 2021.
(60) Provisional application No. 63/892,637, filed on Oct. 2, 2025.

(30) Foreign Application Priority Data
Feb. 25, 2022 (CN) 202220421480.9
Jan. 30, 2026 (CN) 202620133965.6

(51) Int. Cl. H10H 29/856; H10H 29/24

(52) U.S. Cl. CPC H10H 29/856; H10H 29/24

(57) ABSTRACT

A light-emitting package structure and a light-emitting device. The light-emitting package structure includes a substrate, at least one light-emitting unit, a first reflective layer, at least one optical layer, and a second reflective layer. The light-emitting unit and the first reflective layer are disposed on the substrate. The light-emitting unit is surrounded by the first reflective layer and covered by the optical layer. The second reflective layer is disposed on a surface of the first reflective layer away from the substrate. A side surface of the optical layer is surrounded by the second reflective layer. An optical characteristic of the second reflective layer is different from that of the first reflective layer. A width of the optical layer in a first direction is greater than that of the light-emitting unit. A side surface of the second reflective layer does not exceed that of the first reflective layer.

### CROSS-REFERENCE TO RELATED PATENT APPLICATION

This application claims the benefit of priorities to the U.S. Provisional Patent Application Ser. No. 63/168,266, filed on Mar. 31, 2021, Ser. No. 63/180,055, filed on Apr. 26, 2021, and Ser. No. 63/892,637 filed on Oct. 2, 2025, and China Patent Application No. 202220421480.9, filed on Feb. 25, 2022 and No. 202620133965.6, filed on Jan. 30, 2026, in the People's Republic of China. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a structure and a device, and more particularly to a light-emitting package structure and a light-emitting device.

### BACKGROUND OF THE DISCLOSURE

A light-emitting diode (LED) is a semiconductor light-emitting component and has been widely applied in various fields, such as in lighting devices, display devices, and the like.

The packaging technology of the LED is one of the key areas being developed in the current semiconductor industry. Specifically, whether being a wire-bonding packaging technology applied to a lateral LED or a vertical LED, or a flip-chip packaging technology applied to a flip-chip LED, the development is directed toward enhancing brightness, reducing overall size, and improving reliability.

In the flip-chip packaging technology, through appropriate structural design, a chip-scale LED package structure which can achieve the objective of miniaturization of the overall volume has been developed. However, the performance of LED package structures manufactured using chip-scale packaging technology still has substantial room for improvement, particularly in aspects such as brightness and contrast.

### SUMMARY OF THE DISCLOSURE

In response to the above-referenced technical inadequacies, the present disclosure provides a light-emitting package structure and a light-emitting device.

In order to solve the above-mentioned problems, one of the technical aspects adopted by the present disclosure is to provide a light-emitting package structure. The light-emitting package structure includes a substrate, at least one light-emitting unit, a first reflective layer, at least one optical layer, and a second reflective layer. The at least one light-emitting unit is disposed on a surface of the substrate. The first reflective layer is disposed on the surface of the substrate and surrounds the at least one light-emitting unit. The at least one optical layer correspondingly covers the at least one light-emitting unit. The second reflective layer is disposed on a first surface of the first reflective layer that is away from the substrate. A side surface of the at least one optical layer is surrounded by the second reflective layer. An optical characteristic of the second reflective layer is different from an optical characteristic of the first reflective layer. A width of the at least one optical layer in a first direction is greater than a width of the at least one light-emitting unit in the first direction, and a second side surface of the second reflective layer in the first direction does not extend beyond a first side surface of the first reflective layer in the first direction.

In order to solve the above-mentioned problems, another one of the technical aspects adopted by the present disclosure is to provide a light-emitting package structure. The light-emitting package structure includes a substrate, a first reflective layer, a plurality of light-emitting units, a plurality of optical layers, and a second reflective layer. The first reflective layer is disposed on the substrate. The plurality of light-emitting units are arranged spaced apart on the substrate and are each located within the first reflective layer. The plurality of optical layers are respectively disposed corresponding in position to the plurality of light-emitting units. The second reflective layer is disposed on the first reflective layer. The second reflective layer surrounds a side surface of each of the optical layers, and exposes an upper surface of each of the plurality of optical layers. An optical characteristic of the second reflective layer is different from an optical characteristic of the first reflective layer. Along a thickness direction, an orthographic projection of each of the light-emitting units onto the substrate is located within an orthographic projection of each of the optical layers onto the substrate.

In order to solve the above-mentioned problems, yet another one of the technical aspects adopted by the present disclosure is to provide a light-emitting device. The light-emitting device includes a device body and the above-mentioned light-emitting package structure. The light-emitting package structure is disposed within the device body.

Therefore, in the light-emitting package structure and the light-emitting device provided by the present disclosure, by virtue of “the second reflective layer being disposed on a first surface of the first reflective layer that is away from the substrate, and a side surface of the at least one optical layer being surrounded by the second reflective layer,” and “a width of the at least one optical layer in a first direction being greater than a width of the at least one light-emitting unit in the first direction, and a second side surface of the second reflective layer in the first direction not extending beyond a first side surface of the first reflective layer in the first direction,” the light-emitting package structure and the light-emitting device can avoid crosstalk and can enhance light brightness while without sacrificing contrast.

These and other aspects of the present disclosure will become apparent from the following description of the embodiment taken in conjunction with the following drawings and their captions, although variations and modifications therein may be effected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a light-emitting device according to a first embodiment of the present disclosure;

FIG. 2 is a schematic perspective view of a light-emitting package structure according to the first embodiment of the present disclosure;

FIG. 3 is a schematic cross-sectional view taken along line III-III of FIG. 2;

FIG. 4 is a schematic view of another aspect of the light-emitting package structure of FIG. 3;

FIG. 5 is a schematic view of yet another aspect of the light-emitting package structure of FIG. 3;

FIG. 6 is a schematic cross-sectional view of the light-emitting device according to a second embodiment of the present disclosure;

FIG. 7 is a schematic cross-sectional view of the light-emitting device according to a third embodiment of the present disclosure;

FIG. 8 is a schematic enlarged view of region VIII of FIG. 3; and

FIG. 9 is a schematic cross-sectional view of the light-emitting package structure according to the first embodiment of the present disclosure in another implementation.

### DETAILED DESCRIPTION OF THE EXEMPLARY EMBODIMENTS

The present disclosure is more particularly described in the following embodiments and examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

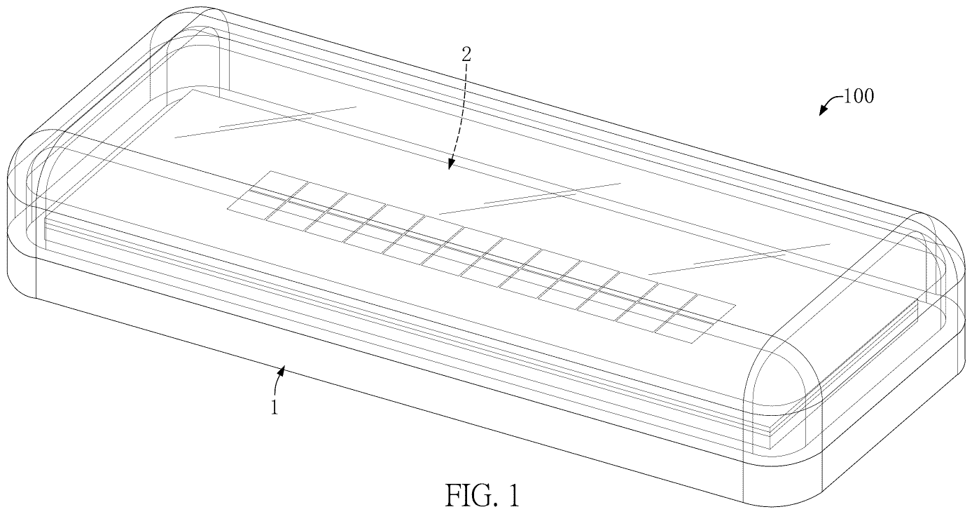

Referring to FIG. 1 to FIG. 5 and FIG. 9, a first embodiment of the present disclosure provides a light-emitting device 100.

As shown in FIG. 1, the light-emitting device 100 includes a device body 1 and a light-emitting package structure 2 disposed within the device body 1. In practical applications, the device body 1 may be, for example, an automotive lamp control module or other types of modules, and the light-emitting package structure 2 can be controlled (and powered) by the device body 1 to generate an expected light source.

It should be noted that although the device body 1 and the light-emitting package structure 2 are collectively defined as the light-emitting device 100 in the present embodiment, the present disclosure is not limited thereto. For example, the light-emitting package structure 2 can be utilized independently (e.g., implemented, manufactured, or sold as a standalone product) or can be used in cooperation with other components. The following description describes the structure and connection relationship of each component of the light-emitting package structure 2.

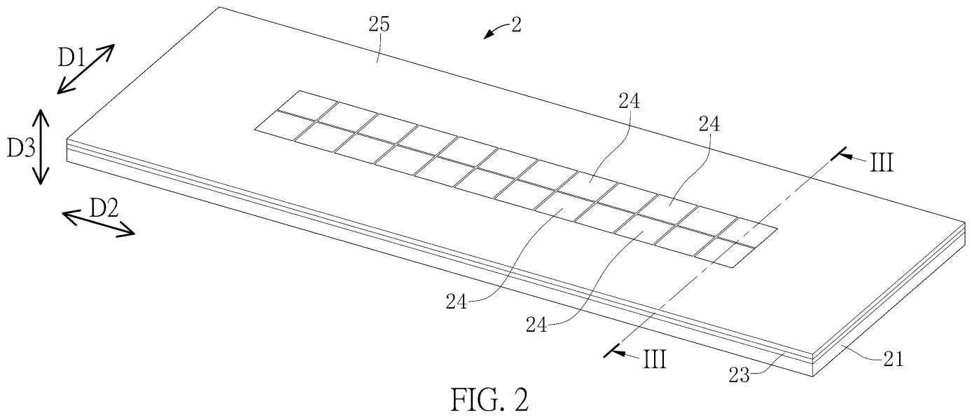

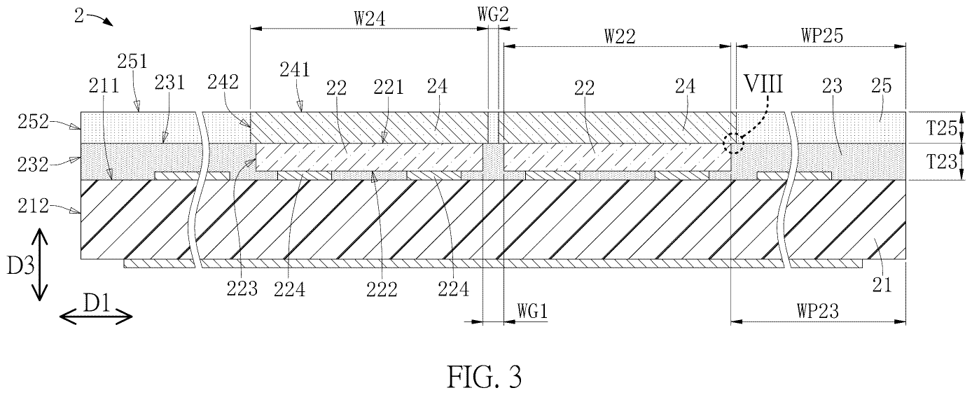

As shown in FIG. 2 and FIG. 3, the light-emitting package structure 2 includes a substrate 21, a plurality of light-emitting units 22 disposed on the substrate 21, a first reflective layer 23 disposed on the substrate 21 and surrounding each of the light-emitting units 22, a plurality of optical layers 24 respectively covering the plurality of light-emitting units 22, and a second reflective layer 25 that surrounds each of the optical layers 24 and covers the first reflective layer 23.

Referring to FIG. 2, the substrate 21 in the present embodiment is a plate-shaped structure having a substantially rectangular form. However, this configuration is provided merely by way of example, and the substrate 21 may be modified into other shapes, and the present disclosure is not limited thereto. In the present embodiment, an extending direction of a width of the substrate 21 is defined as a first direction D1 (that is, the first direction D1 can also be referred to as a width direction), an extending direction of a length of the substrate 21 is defined as a second direction D2 (that is, the second direction D2 can also be referred to as a length direction), and an extending direction of a thickness of the substrate 21 is defined as a third direction D3 (that is, the third direction D3 can also be referred to as a thickness direction). That is to say, the second direction D2 is perpendicular to the first direction D1 and the third direction D3. In the present embodiment, the width of the substrate 21 along the first direction D1 is less than the length of the substrate 21 along the second direction D2, and the thickness of the substrate 21 along the third direction D3 is less than the width of the substrate 21. However, the descriptions above are provided only as an illustrative example, and the dimensions and the shape of the substrate 21 are not limited thereto.

Referring to FIG. 2 and FIG. 3, in the present embodiment, the plurality of light-emitting units 22 are arranged on the substrate 21 in an N by M array along the first direction D1 and the second direction D2. For example, the array may be configured as a 2 by 12 matrix; however, the present disclosure is not limited thereto. A gap between any two adjacent ones of the light-emitting units 22 has a predetermined width WG1, and the predetermined width WG1 may be adjusted according to practical requirements within a range from 50 micrometers to 600 micrometers. That is, the plurality of light-emitting units 22 are arranged in a compact configuration.

In addition, for the convenience of description, in FIG. 2 to FIG. 5, the light-emitting package structure 2 is illustrated in a cross-section taken along line III-III. Accordingly, the cross-section of the light-emitting package structure 2 in FIG. 2 to FIG. 5 only presents two of the light-emitting units 22.

Specifically, each of the light-emitting units 22 can be a flip chip. In appearance, each of the light-emitting units 22 has a top surface 221, a bottom surface 222, side surfaces 223, and an electrode portion 224. The top surface 221 and the bottom surface 222 are arranged opposite to each other in the third direction D3, and the side surfaces 223 are located between the top surface 221 and the bottom surface 222. That is to say, the side surfaces 223 connect the top surface 221 and the bottom surface 222 and faces the first direction D1 and the second direction D2.

On the other hand, the electrode portion 224 is arranged on the bottom surface 222 and may have two or more electrodes, for example, a positive electrode and a negative electrode. Each of the light-emitting units 22 can be mounted on the substrate 21 through the electrode portion 224, and the plurality of light-emitting units 22 are arranged spaced apart from each other in the first direction D1. Furthermore, electrical power (not shown) can be supplied into each of the light-emitting units 22 through the electrode portion 224, thereby enabling each of the light-emitting units 22 to emit light. Most of the light emitted from each of the light-emitting units 22 exits through the top surface 221, which serves as a light-emitting surface.

Referring to FIG. 3, the first reflective layer 23 is arranged on the substrate 21 and surrounds the side surfaces 223 of each of the light-emitting units 22. The top surface 221 of each of the light-emitting units 22 is exposed from the first reflective layer 23. In practice, for example, the first reflective layer 23 may be formed during the manufacturing process by curing a liquefied first reflective material. That is to say, the liquefied first reflective material fills the gaps between the substrate 21 and any two adjacent ones of the light-emitting units 22, and is then cured to form the first reflective layer 23 without covering the top surface 221 of each of the light-emitting units 22.

In another embodiment, the first reflective layer 23 may further cover a portion of the bottom surface 222 of each of the light-emitting units 22. That is to say, a portion of the first reflective layer 23 may fill the gaps between any two adjacent ones of the light-emitting units 22, as well as a gap at the electrode portion 224 (for example, a space between two electrodes), without covering a contact surface between the electrode portion 224 and the substrate 21. However, the present disclosure is not limited to configurations in which the first reflective layer 23 surrounds the bottom surface 222 of each of the light-emitting units 22. For example, in another embodiment of the present disclosure (not shown), the bottom surface 222 of each of the light-emitting units 22 is not covered by the first reflective layer 23.

On the other hand, in a manufacturing process of the light-emitting package structure 2, a portion of the liquefied first reflective material may initially cover the top surface 221 of each of the plurality of light-emitting units 22. When the liquefied first reflective material is cured, the portions of the first reflective material corresponding to the top surface 221 of each of the light-emitting units 22 is removed through a processing step, such that the remaining cured first reflective material forms the first reflective layer 23.

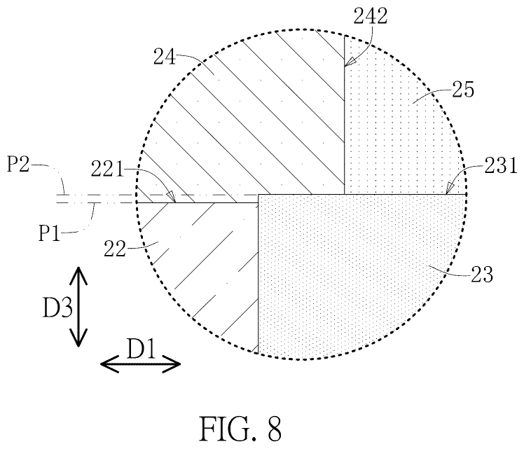

In an embodiment, as shown in FIG. 8, which is an enlarged schematic view of region VIII of FIG. 3, a first height position P1 of the top surface 221 of each of the light-emitting units 22 relative to the substrate 21 is equal to or lower than a second height position P2 of a first surface 231 of the first reflective layer 23 relative to the substrate 21. In other words, the top surface 221 of each of the light-emitting units 22 may be flush with the first surface 231 of the first reflective layer 23, or the top surface 221 of each of the light-emitting units 22 may be slightly lower than the first surface 231 of the first reflective layer 23. Preferably, when the first height position P1 is lower than the second height position P2, a height difference of approximately 10 micrometers exists between the first height position P1 and the second height position P2.

It should be noted that, as shown in FIG. 3, a first side surface 232 of the first reflective layer 23 in the first direction D1 may not extend beyond a side surface 212 of the substrate 21 in the first direction D1.

For example, in one embodiment of the light-emitting package structure 2 shown in FIG. 3, the first side surface 232 of the first reflective layer 23 is flush with a side surface 212 of the substrate 21.

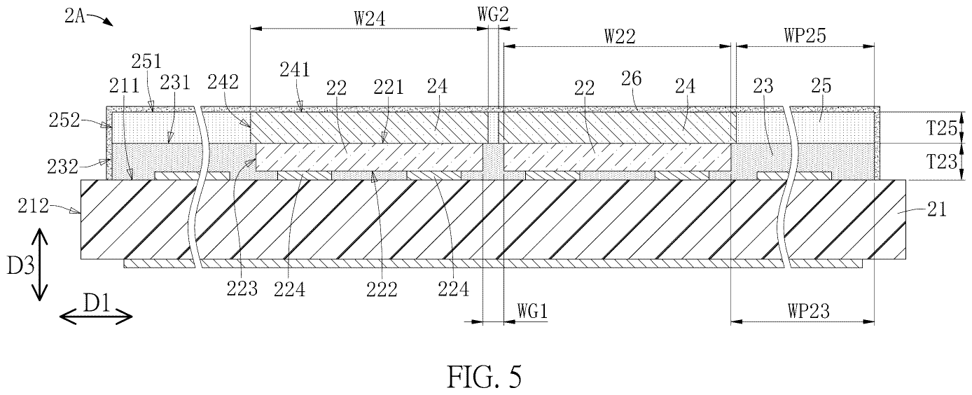

As another example, in another embodiment of the light-emitting package structure 2A shown in FIG. 5, a surface of the substrate 21 facing the plurality of light-emitting units 22 is defined as a top surface 211. A portion of the top surface 211 of the substrate 21 is covered by the first reflective layer 23, and another portion of the top surface 211 of the substrate 21 is exposed outside the first reflective layer 23.

Referring again to FIG. 3, a plurality of optical layers 24 respectively correspond to and cover the top surfaces 221 of the plurality of light-emitting units 22, such that light emitted from each of the light-emitting units 22 can pass through the corresponding optical layer 24 to be emitted outward. In other words, the plurality of optical layers 24 are made of a light-permeable material, and a quantity of the plurality of optical layers 24 may correspond to a quantity of the plurality of light-emitting units 22.

In practice, each of the optical layers 24 may preferably be selected as an optical layer 24 having phosphors or an optical layer 24 having optical diffusivity according to practical requirements; that is, each of the optical layers 24 may be a phosphor layer, a light diffusion layer, or at least one of these, but the present disclosure is not limited thereto.

Preferably, a width W24 of each of the optical layers 24 in the first direction D1 is greater than or equal to a width W22 of each of the light-emitting units 22 in the first direction D1. In practice, an orthographic projection of each of the light-emitting units 22 onto the substrate 21 is entirely located within an orthographic projection of each of the corresponding optical layers 24 onto the substrate 21. In other words, a region of each of the light-emitting units 22 projected onto the substrate 21 along the third direction D3 (i.e., the thickness direction) is located within a region of each of the corresponding optical layers 24 projected onto the substrate 21 along the third direction D3. In addition, it should be noted that a gap having a predetermined width WG2 exists between any two adjacent optical layers 24, and the predetermined width WG2 is not greater than the predetermined width WG1. That is, a spacing distance between any two adjacent ones of the optical layers 24 may be equal to or less than a spacing distance between any two adjacent ones of the light-emitting units 22. In one embodiment, the predetermined width WG2 may be designed according to practical requirements within a range from 30 micrometers to 500 micrometers.

Referring to FIG. 3, the second reflective layer 25 covers a surface of the first reflective layer 23 that is away from the substrate 21 (i.e., a first surface 231 of the first reflective layer 23), and a portion of the second reflective layer 25 is located between the plurality of optical layers 24. In the present embodiment, a width of the portion of the second reflective layer 25 located between any two adjacent ones of the optical layers 24 in the first direction D1 is substantially equal to the width WG2. A material composition of the second reflective layer 25 is different from that of the first reflective layer 23, and the second reflective layer 25 has an optical characteristic different from that of the first reflective layer 23 (hereinafter referred to as optical characteristic difference).

In the present embodiment, the optical characteristic difference between the second reflective layer 25 and the first reflective layer 23 may be configured according to practical requirements, such that a reflectivity of the second reflective layer 25 is less than a reflectivity of the first reflective layer 23.

In order to achieve the aforementioned optical characteristic difference, in practice, the second reflective layer 25 may include a matrix and a colored material. The matrix may be, for example, silicone resin, epoxy resin, or a mixture thereof, and the colored material may be a white light-reflecting/light-scattering substance and/or a dark/black substance with light-shielding/light-absorbing characteristics. In the present embodiment, the white material may include, for example, titanium dioxide, silicon dioxide, or similar substances, while the dark/black material may include, for example, a plurality of light-absorbing particles (e.g., carbon black). As a result, the second reflective layer 25 has functions of partial light reflection and partial light absorption. Detailed examples are provided below.

Compared to the first reflective layer 23, the second reflective layer 25 further includes a plurality of light-absorbing particles (e.g., carbon black) or light-shielding materials. Preferably, a weight percentage of the plurality of light-absorbing particles doped in the second reflective layer 25 may be adjusted according to practical requirements within a range from 0.05% to 10%.

A weight percentage of the plurality of light-absorbing particles doped in the second reflective layer 25 may be adjusted inversely proportional to “a width of a portion of the second reflective layer 25 located between any two adjacent optical layers 24 in the first direction D1.”

For example, a manufacturing process of the second reflective layer 25 in practice is similar to that of the first reflective layer 23. The second reflective layer 25 is likewise formed by curing a liquefied second reflective material. The second reflective material contains a plurality of light-absorbing particles or light-shielding materials, and the liquefied second reflective material covers a first surface 231 of the first reflective layer 23 and into the gap (i.e., the width WG2) between any two adjacent ones of the optical layers 24, and is then cured to form the second reflective layer 25 without covering a top surface 241 of each of the optical layers 24.

In another aspect, in a manufacturing process of the light-emitting package structure 2, the liquefied second reflective material may first be applied to completely cover both the first surface 231 of the first reflective layer 23 and the top surfaces 241 of the plurality of optical layers 24. When the liquefied second reflective material is cured, the portion of the second reflective material at a position corresponding to the top surface 241 of each of the optical layers 24 is removed through a processing step, such that the remaining cured second reflective material forms the second reflective layer 25.

Preferably, a second surface 251 of the second reflective layer 25 which is away from the substrate 21 is substantially flush with the top surfaces 241 of the plurality of optical layers 24, but the present disclosure is not limited thereto. In another embodiment, for example, the second surface 251 of the second reflective layer 25 may alternatively be positioned above or below the top surfaces 241 of the plurality of optical layers 24.

On the other hand, when an observer observes a cross-section of the light-emitting package structure 2 taken along line III-III (for example, FIG. 3) which is parallel to the first direction D1 and passes through any one of the light-emitting units 22, the observer can find that the second reflective layer 25 laterally extends from a side surface 242 of each of the plurality of optical layers 24 in the first direction D1.

In order to ensure that the first reflective layer 23 contributes to redirecting and re-utilizing the light leaking laterally from each of the light-emitting units 22, and to prevent crosstalk between the optical layers 24, a width W24 of each of the optical layers 24 in the first direction D1 is greater than a width W22 of each of the light-emitting units 22 in the first direction D1. In addition, a second side surface 252 of the second reflective layer 25 in the first direction D1 does not extend beyond the first side surface 232 of the first reflective layer 23 in the first direction D1.

In other words, under a configuration in which the width W24 of each of the optical layers 24 is greater than the width W22 of each of the light-emitting units 22, and the second side surface 252 of the second reflective layer 25 does not extend beyond the first side surface 232 of the first reflective layer 23, a portion of the first reflective layer 23 extending from the side surface 223 of any one of the light-emitting units 22 along the first direction D1 has a first width WP23, and a portion of the second reflective layer 25 extending from the side surface 242 of each of the optical layers 24 along the first direction D1 has a second width WP25. The first width WP23 is greater than the second width WP25.

In another embodiment, a portion of the first reflective layer 23 facing any one of the light-emitting units 22 along the first direction D1 may further extend to the bottom surface 222 of the light-emitting unit 22, such that the first width WP23 is necessarily greater than the second width WP25.

Preferably, the first width WP23 may be designed according to practical requirements within a range from 0.05 millimeters to 35 millimeters, and the second width WP25 may be designed according to practical requirements within a range from 0.03 millimeters to 30 millimeters.

Furthermore, in the present embodiment, the second side surface 252 of the second reflective layer 25 in the first direction D1 is flush with a first side surface 232 of the first reflective layer 23 in the first direction D1.

Accordingly, the light-emitting package structure 2 forms a stepped stacked structure by the first reflective layer 23 and the second reflective layer 25, which have different optical characteristics. More specifically, at least one side surface of the first reflective layer 23 and the second reflective layer 25 in the first direction D1 exhibits a non-aligned arrangement (in other words, widths of the first reflective layer 23 and the second reflective layer 25 in the first direction D1 are not equal), and the width of the first reflective layer 23 in the first direction D1 is greater than the width of the second reflective layer 25 in the first direction D1.

In the present embodiment, the reflectivity of the first reflective layer 23 is greater than the reflectivity of the second reflective layer 25. Accordingly, the lateral light emitted from each of the light-emitting units 22 can be effectively reflected by the first reflective layer 23 toward the overlying optical layer 24, thereby preventing optical crosstalk between adjacent light-emitting units 22 and improving the luminous efficiency of each light-emitting unit 22. Furthermore, even if a portion of light reflected from the first reflective layer 23 and light emitted from the top surface 221 of each of the light-emitting units 22 are transmitted to the side surface 242 of the optical layer 24, such light can still be partially reflected and partially absorbed by the second reflective layer 25, thereby preventing crosstalk and enhance contrast. It is worth noting that since the width WP25 of the second reflective layer 25 in the first direction D1 is less than the width WP23 of the first reflective layer 23 in the first direction D1, the light-emitting package structure can still achieve excellent light intensity even though a portion of the lateral light is absorbed. In other words, by providing the first reflective layer 23 and the second reflective layer 25 with different optical characteristics and arranging them in a stepped stacked architecture, the light-emitting package structure 2 can, under a compact configuration (i.e., a small pitch between the light-emitting units 22), prevent crosstalk while simultaneously achieving both improved contrast and enhanced brightness.

In addition, to further enhance the aforementioned effects of the light-emitting package structure 2, a thickness of the first reflective layer 23 may also be designed according to practical requirements to be greater than a thickness of the second reflective layer 25. In other words, in a cross-section of the light-emitting package structure 2 along the first direction D1 or the second direction D2, a second predetermined thickness T25 of the second reflective layer 25 along the third direction D3 is less than a first predetermined thickness T23 of the first reflective layer 23 along the third direction D3. In practice, the first predetermined thickness T23 does not exceed 150 micrometers, and the second predetermined thickness T25 does not exceed 120 micrometers, but the present disclosure is not limited thereto. In another embodiment (not shown), the thickness T23 of the first reflective layer 23 may also be adjusted according to practical requirements to be substantially equal to the thickness T25 of the second reflective layer 25.

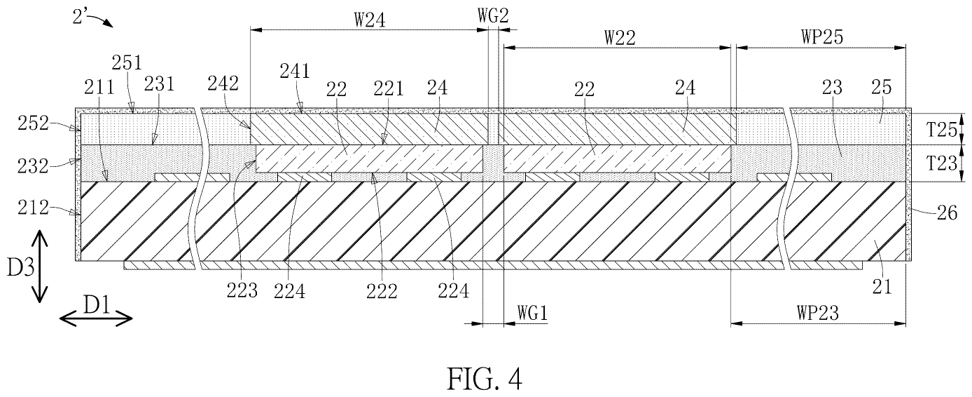

It is worth mentioning that, in order to ensure reliability and improve service life of the light-emitting package structure 2 may further include a protective layer 26, as shown in FIG. 4 in another embodiment of the present disclosure. In practice, the protective layer 26 of a light-emitting package structure 2′ may be a fluorinated layer, an inorganic silicon dioxide layer, or at least one of the foregoing. The protective layer 26 covers at least one of the optical layer 24, the second reflective layer 25, or the first reflective layer 23. In another embodiment, except for a surface of a component that needs to be exposed (for example, the electrode portion), the protective layer 26 can further extend to cover a surface of the substrate 21 of the light-emitting package structure 2′ to avoid moisture from penetrating into an interior of the light-emitting package structure 2′, thereby improving product reliability and durability.

In order to further understand an improvement in optical performance of the light-emitting package structure 2 of the present embodiment compared to a conventional light-emitting package structure, a data comparison between the light-emitting package structure 2 and the conventional light-emitting package structure is provided below.

The light-emitting package structure 2 of the present disclosure performs significantly better in terms of light-emitting intensity than the conventional light-emitting package structure. Using the conventional light-emitting package structure as a reference (100%), the luminous efficiency of the light-emitting package structure 2 is improved by approximately 28.3%. In addition, in terms of production cost, the light-emitting package structure 2 has a significant competitive advantage, as its manufacturing cost can be saved by approximately 30%. Furthermore, the light-emitting package structure 2 also greatly improves production stability, resulting in a significant increase in yield and a significant reduction in defect rate. In a power temperature cycling test, the light-emitting package structure 2 also successfully passed the test to demonstrate that the light-emitting package structure 2 has improved stability and durability under extreme conditions or long-term operation.

It should be noted that the light-emitting package structure 2 of the present disclosure includes a plurality of light-emitting units 22 in the present embodiment, but the present disclosure is not limited thereto. For example, in another embodiment of the present disclosure, the light-emitting package structure 2 may include only a single light-emitting unit 22.

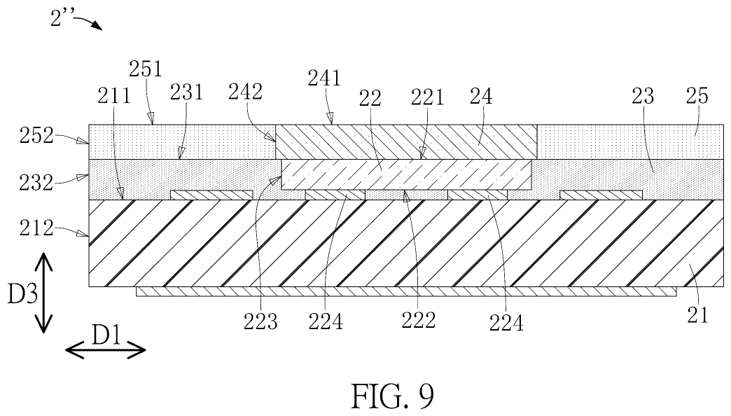

As shown in FIG. 9, a light emitting package structure 2″ comprises a substrate 21, a light-emitting unit 22, a first reflective layer 23, an optical layer 24 and a second reflective layer 25 having light absorbing/blocking function. The light-emitting unit 22 has a top surface 221, a bottom surface 222 and side surfaces 223. The side surfaces 223 are between the top surface 221 and the bottom surface 222. The light-emitting unit 22 may be a flip chip, and has electrode portion 224 on the bottom surface 222. In one embodiment, the light-emitting unit 22 comprises a light emitting diode (LED) chip, such as a blue LED chip.

In this embodiment, the light-emitting unit 22 and the first reflective layer 23 are disposed on a surface 211 of the substrate 21. The electrode portion 224 of the light-emitting unit 22 may be electrically connected to an external circuit through conductive elements of the substrate 21 so as to drive the light-emitting unit 22.

The first reflective layer 23 encloses the side surfaces 223 of the light emitting unit 22. For example, the light emitting unit 22 of a rectangular shape has four sidewall surfaces, the first reflective layer 23 surrounds the four sidewall surfaces of the light emitting unit 22. A first surface 231 of the first reflective layer 23 and the top surface 221 of the light emitting unit 22 are substantially level with each other. The first reflective layer 23 may be, for example, formed of a resin mixture containing reflective particles. In a preferred embodiment, the first reflective layer 23 has a reflectance of 95% or higher to a light emitted from the light emitting unit 22, and therefore can effectively reflect a lateral light from the light emitting unit 22 to provide a better light-collection effect.

The optical layer 24 may be disposed on the top surface 221 of the light-emitting unit 22 and the first surface 231 of the first reflective layer 23. The optical layer 24 may comprise a phosphor layer, a light diffusion layer or a combination thereof. In one embodiment, the phosphor layer 24 provides a wavelength converting effect to a light emitted from the light-emitting unit 22, thereby generating light of various colors different from a color of the light emitted from the light-emitting unit 22 for the light emitting package structure 2″. In another embodiment, the phosphor layer 24 serves as a light diffusion layer to provide a light-equalizing effect. In yet another embodiment, the optical layer 24 includes both the phosphor layer and the light diffusion layer, wherein the phosphor layer is disposed on the top surface 221 of the light-emitting unit 22, and the light diffusion layer is disposed on a top surface of the phosphor layer. The light diffusion layer of the optical layer 24 may have a transmittance of 99% or higher. The material of the light diffusion layer of the optical layer 24 may comprise silicon dioxide, titanium dioxide, boron nitride, or combinations thereof, etc.

The second reflective layer 25, which functions as a light blocking layer, is disposed on the top surface 231 of the first reflective layer 23. The second reflective layer 25 (e.g., light blocking layer) encloses side surfaces 242 of the optical layer 24. A second side surface 252 of the second reflective layer 25 (e.g., light blocking layer) and a first side surface 232 of the first reflective layer 23 are substantially flush with each other. In addition, a second surface 251 of the second reflective layer 25 (e.g., light blocking layer) is substantially level with a top surface 241 of the optical layer 24. The second reflective layer 25 may be a light absorbing element having a dark color or a black color. The second reflective layer 25 may have a light transmittance of 5% or lower, the material of the second reflective layer 25 comprises a mixture of a resin and carbon black, for example. The second reflective layer 25 can block/absorb an emitting light of large angle, by which a contrast ratio of the arrayed light emitting package structures can be increased.

### Second Embodiment

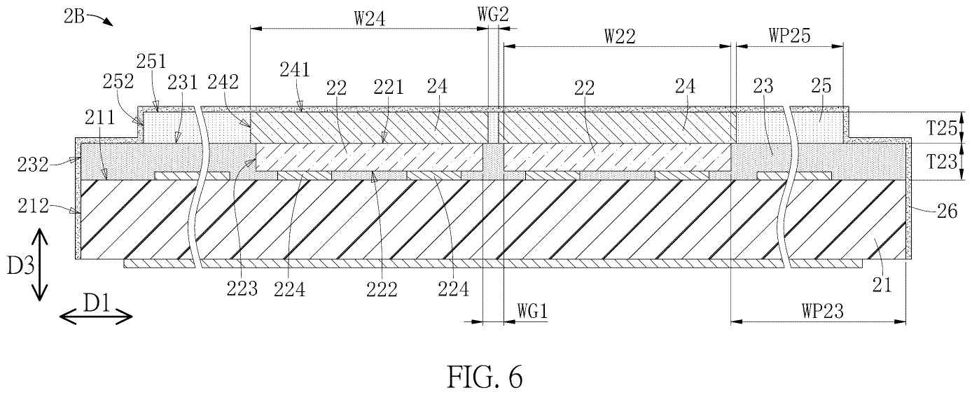

Referring to FIG. 6, a second embodiment of the present disclosure provides a light-emitting package structure 2B. The present embodiment is similar to the first embodiment, and the similarities therebetween will not be repeated herein. The difference between the present embodiment and the first embodiment mainly lies in that the second reflective layer 25 does not completely cover the first surface 231 of the first reflective layer 23, such that a portion of the first surface 231 of the first reflective layer 23 is exposed.

Specifically, a surface of the first reflective layer 23 opposite to the substrate 21 is defined as a first surface 231. A portion of the first surface 231 of the first reflective layer 23 is covered by the second reflective layer 25, while another portion of the first surface 231 of the first reflective layer 23 is exposed outside the second reflective layer 25 and is defined as a stepped surface.

In other words, a width of a portion of the second reflective layer 25 that extends along the first direction D1 from the side surface 242 of each of the optical layers 24 (i.e., the second width WP25) is reduced. That is to say, the second width WP25 is less than the first width WP23. As a result, the first reflective layer 23 and the second reflective layer 25 jointly form a step-like profile.

Similarly, in order to ensure reliability and improve service life of the light-emitting package structure 2B, the light-emitting package structure 2B may further include a protective layer 26. In practice, the protective layer 26 can cover at least the optical layer 24, the second reflective layer 25, and the first reflective layer 23. In another embodiment, except for a surface of a component that needs to be exposed (e.g., the electrode portion), the protective layer 26 may further extend to cover a surface of the substrate 21 of the light-emitting package structure 2B to prevent moisture from penetrating into an interior of the light-emitting package structure 2B, thereby improving product reliability and durability.

### Third Embodiment

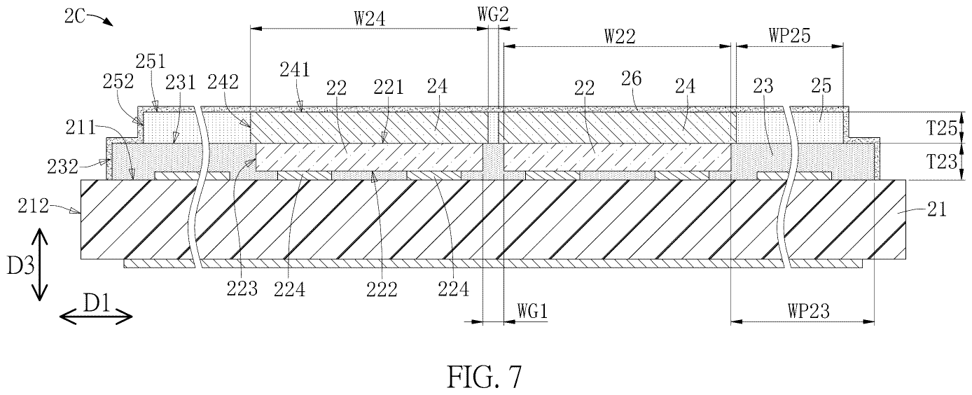

Referring to FIG. 7, a third embodiment of the present disclosure provides a light-emitting package structure 2C. The present embodiment is similar to the second embodiment, and the similarities therebetween will not be repeated herein. The difference between the present embodiment and the second embodiment mainly lies in that the first reflective layer 23 does not completely cover the surface 211 of the substrate 21, such that a portion of the surface 211 of the substrate 21 is exposed.

Specifically, the substrate 21 has a surface 211 facing the plurality of light-emitting units 22. A portion of the surface 211 of the substrate 21 is covered by the first reflective layer 23, while another portion of the surface 211 of the substrate 21 is exposed outside the first reflective layer 23 and is defined as a first stepped surface (not labeled).

The first reflective layer 23 has a first surface 231 facing away from the substrate 21. A portion of the first surface 231 of the first reflective layer 23 is covered by the second reflective layer 25, while another portion of the first surface 231 of the first reflective layer 23 is exposed outside the second reflective layer 25 and is defined as a second stepped surface (not labeled).

In other words, a width of a portion of the first reflective layer 23 that extends along the first direction D1 from the side surface 223 of each of the light-emitting units 22 (i.e., the first width WP23) is reduced, and a width of a portion of the second reflective layer 25 that extends along the first direction D1 from the side surface 242 of each of the optical layers 24 (i.e., the second width WP25) is reduced. Accordingly, the substrate 21, the first reflective layer 23, and the second reflective layer 25 jointly form two-stepped profile.

In order to further understand an improvement in optical characteristics of the light-emitting package structure 2C of the present embodiment compared to a conventional light-emitting package structure, a comparison of performance data between the light-emitting package structure 2C and the conventional light-emitting package structure is provided below.

The light-emitting package structure 2C of the present disclosure performs significantly better in light-emitting intensity than the conventional light-emitting package structure. Using the conventional light-emitting package structure as a baseline (100%), the luminous efficiency of the light-emitting package structure 2C is improved by approximately 36.6%. In addition, in terms of production cost, the light-emitting package structure 2C has a significant competitive advantage, as its manufacturing cost can be saved by approximately 30%. Furthermore, the light-emitting package structure 2C also greatly improves production stability, resulting in a significant increase in yield and a significant reduction in defect rate. The light-emitting package structure 2C also successfully passes power-temperature cycling tests, demonstrating its superior stability and durability under extreme environmental conditions or long-term operation.

### Beneficial Effects of the Embodiments

In conclusion, the light-emitting package structure and the light-emitting device disclosed in the embodiments of the present disclosure, by virtue of “the second reflective layer being disposed on a first surface of the first reflective layer that is away from the substrate, and a side surface of the at least one optical layer being surrounded by the second reflective layer,” “the second reflective layer having optical characteristics different from those of the first reflective layer,” and “a width of the at least one optical layer in a first direction being greater than a width of the at least one light-emitting unit in the first direction, and a second side surface of the second reflective layer in the first direction not extending beyond a first side surface of the first reflective layer in the first direction,” the light-emitting package structure and the light-emitting device are capable of preventing optical crosstalk and can enhance light brightness while without sacrificing contrast.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A light-emitting package structure, comprising:
a substrate;
at least one light-emitting unit disposed on a surface of the substrate;
a first reflective layer disposed on the surface of the substrate and surrounding the at least one light-emitting unit;
at least one optical layer correspondingly covering the at least one light-emitting unit; and
a second reflective layer disposed on a first surface of the first reflective layer that is away from the substrate; wherein a side surface of the at least one optical layer is surrounded by the second reflective layer;
wherein an optical characteristic of the second reflective layer is different from an optical characteristic of the first reflective layer; and
wherein a width of the at least one optical layer in a first direction is greater than a width of the at least one light-emitting unit in the first direction, and a second side surface of the second reflective layer in the first direction does not extend beyond a first side surface of the first reflective layer in the first direction.

2. The light-emitting package structure according to claim 1, wherein a quantity of the at least one light-emitting unit and a quantity of the at least one optical layer are both plural, the plurality of light-emitting units are disposed on the substrate in a spaced-apart arrangement from each other along the first direction, and the plurality of optical layers are respectively disposed corresponding in position to the plurality of light-emitting units.

3. The light-emitting package structure according to claim 2, wherein a portion of the second reflective layer is located between the plurality of optical layers.

4. The light-emitting package structure according to claim 1, wherein, in a cross-section of the light-emitting package structure taken along the first direction or a second direction that is perpendicular to the first direction, a second predetermined thickness of the second reflective layer along a third direction perpendicular to both the first direction and the second direction is less than a first predetermined thickness of the first reflective layer along the third direction.

5. The light-emitting package structure according to claim 4, wherein the first predetermined thickness is less than or equal to 150 micrometers, and the second predetermined thickness is less than or equal to 120 micrometers.

6. The light-emitting package structure according to claim 1, wherein a portion of the first reflective layer extending along the first direction has a first width, a portion of the second reflective layer extending along the first direction has a second width, and the first width is greater than the second width.

7. The light-emitting package structure according to claim 6, wherein the first width is within a range from 0.05 millimeters to 35 millimeters, and the second width is within a range from 0.03 millimeters to 30 millimeters.

8. The light-emitting package structure according to claim 1, wherein a top surface of the at least one light-emitting unit has a first height position relative to the substrate, and a first surface of the first reflective layer has a second height position relative to the substrate, and wherein the first height position is equal to or lower than the second height position.

9. The light-emitting package structure according to claim 1, wherein, along the first direction, the first side surface of the first reflective layer does not extend beyond a side surface of the substrate.

10. The light-emitting package structure according to claim 9, wherein, along the first direction, the second side surface of the second reflective layer is flush with the first side surface of the first reflective layer.

11. The light-emitting package structure according to claim 9, wherein a portion of the first surface of the first reflective layer is covered by the second reflective layer, and another portion of the first surface of the first reflective layer is exposed outside the second reflective layer and is defined as a stepped surface.

12. The light-emitting package structure according to claim 9, wherein a portion of the surface of the substrate is covered by the first reflective layer, and another portion of the surface of the substrate is exposed outside the first reflective layer and is defined as a first stepped surface.

13. The light-emitting package structure according to claim 12, wherein, in the first direction, the second side surface of the second reflective layer is flush with the first side surface of the first reflective layer.

14. The light-emitting package structure according to claim 12, wherein a portion of the first surface of the first reflective layer is covered by the second reflective layer, and another portion of the first surface of the first reflective layer is exposed outside the second reflective layer and is defined as a second stepped surface.

15. The light-emitting package structure according to claim 1, wherein the light-emitting package structure further comprising a protective layer, and wherein the protective layer covers at least one of the at least one optical layer, the second reflective layer, or the first reflective layer.

16. The light-emitting package structure according to claim 15, wherein the protective layer is at least one of a fluorinated layer and an inorganic silicon dioxide layer.

17. The light-emitting package structure according to claim 3, wherein, along the first direction, a portion of the second reflective layer located between any two adjacent ones of the optical layers has a predetermined width, and the predetermined width is within a range from 30 micrometers to 500 micrometers.

18. The light-emitting package structure according to claim 15, wherein the second reflective layer comprises a plurality of light-absorbing particles or light-shielding materials.

19. The light-emitting package structure according to claim 18, wherein a weight percentage of the plurality of light-absorbing particles or the light-shielding materials doped in the second reflective layer is within a range from 0.05% to 10%.

20. The light-emitting package structure according to claim 1, wherein the second reflective layer comprises carbon black and silicone resin, epoxy resin, or a mixture thereof.

21. The light-emitting package structure according to claim 8, wherein the at least one light-emitting unit has a bottom surface opposite to the top surface, an electrode portion is disposed on the bottom surface, the at least one light-emitting unit is disposed on the substrate through the electrode portion to form an electrical connection, and wherein a portion of the bottom surface of the at least one light-emitting unit is covered by the first reflective layer.

22. The light-emitting package structure according to claim 1, wherein the at least one optical layer is at least one of a phosphor layer and a light diffusion layer.

23. The light-emitting package structure according to claim 1, wherein a reflectivity of the second reflective layer is less than a reflectivity of the first reflective layer.

24. A light-emitting package structure, comprising:
a substrate;
a first reflective layer disposed on the substrate;
a plurality of light-emitting units arranged spaced apart on the substrate and each located within the first reflective layer;
a plurality of optical layers respectively disposed corresponding in position to the plurality of light-emitting units; and
a second reflective layer disposed on the first reflective layer, the second reflective layer surrounding a side surface of each of the optical layers, and exposing an upper surface of each of the plurality of optical layers;
wherein an optical characteristic of the second reflective layer is different from an optical characteristic of the first reflective layer; and
wherein, along a thickness direction, an orthographic projection of each of the light-emitting units onto the substrate is located within an orthographic projection of each of the optical layers onto the substrate.

25. The light-emitting package structure according to claim 24, wherein, in a width direction, a second side surface of the second reflective layer does not extend beyond a first side surface of the first reflective layer.

26. A light-emitting device, comprising:
a device body; and
the light-emitting package structure according to claim 1, wherein the light-emitting package structure is disposed within the device body.
